(19) United States
(12) Patent Application Publication
(10) Pub. No.: US 2025/0338452 A1
(43) Pub. Date: Oct. 30, 2025

(54) Smart Liquid Cooling Manifold

(71) Applicant: Dell Products L.P., Round Rock, TX (US)

(72) Inventors: Eric Michael Tunks, Austin, TX (US); Ben John Sy, Austin, TX (US)

(73) Assignee: Dell Products L.P., Round Rock, TX (US)

(21) Appl. No.: 18/651,380

(22) Filed: Apr. 30, 2024

(51) Int. Cl. H05K 7/20

(52) U.S. Cl. CPC H05K 7/20772; H05K 7/20272

(57) ABSTRACT

A cooling manifold for distributing liquid coolant to a plurality of liquid cooled information handling systems includes a temperature sensor, a pressure sensor, and a flow meter for detecting coolant temperature, pressure, and flow rate respectively. The cooling manifold may further be associated with a data acquisition device configured to convert signals representing temperature, pressure, and flow rate from the sensors to data signals and transmit the data signals to a data center building management system via a power distribution unit.

### BACKGROUND

As the value and use of information continues to increase, individuals and businesses seek additional ways to process and store information. One option available to users is Information Handling Systems (IHSs). An IHS generally processes, compiles, stores, and/or communicates information or data for business, personal, or other purposes thereby allowing users to take advantage of the value of the information. IHS's may assume different form factors including, but not limited to: servers, workstations, desktops, laptops, appliances, video game consoles, tablets, smartphones, etc. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Groups of IHSs may be housed within data center environments. A data center may include a large number of IHSs, such as enterprise blade servers that are stacked and installed within computing racks, which may also be referred to as racks. A data center may include large numbers of such computing racks that are organized into rows of racks. Administration of such large groups of IHSs may require teams of remote and local administrators working in shifts in order to support around-the-clock availability of the data center operations while minimizing any downtime.

Racks provide a means for densely housing relatively large numbers of individual computing devices. A principal challenge with such dense packaging often involves providing sufficient cooling for each of the computing devices. Many newer computing rack designs have implemented liquid cooling systems, such as liquid immersion cooling, or liquid cooling provided by cold plates that are thermally coupled to the principal heat generating components of the individual computing device.

### SUMMARY

The present disclosure is directed to embodiments of a computing rack smart liquid cooling manifold for distributing liquid coolant to a plurality of liquid cooled information handling systems includes a temperature sensor, a pressure sensor, and a flow meter for detecting coolant temperature, pressure, and flow rate respectively. The cooling manifold may further be associated with a data acquisition device configured to convert signals representing temperature, pressure, and flow rate from the sensors to data signals and transmit the data signals to a data center building management system via a power distribution unit associated with the information handling systems.

In one embodiment, the cooling manifold may further include a leak detector.

Another aspect of the disclosure relates to a method for temperature management for a plurality of liquid cooled information handling systems comprising the steps of associating a manifold with the plurality of information handling systems, where the manifold configured to distribute liquid coolant to each of the plurality of information handling systems. The manifold includes a plurality of sensors, each of the plurality of sensors is configured to generate a signal representing coolant temperature, coolant pressure or coolant flow rate.

In another aspect, the method includes converting the signal to a digital data signal and transmitting the digital data signal to a management system, which may be a building management system for a data center in which the information handling systems are housed.

In yet another aspect, the method further includes the steps of either throttling performance of the information handling systems based upon the digital data signal, or shutting down the information handling systems based upon the digital data signal.

### BRIEF DESCRIPTION OF THE DRAWINGS

The present apparatus is illustrated by way of example and is not limited by the accompanying figures. Elements in the figures are illustrated for simplicity and clarity and have not necessarily been drawn to scale. In the drawings, like reference numbers indicate identical or functionally similar elements. Additionally, the left-most digit(s) of a reference number identifies the drawing in which the reference number first appears.

FIG. 1 is a block diagram illustrating a direct liquid cooling system for a data center facility;

FIG. 2 is a partial, perspective view illustrating an example computing rack that may be used to mount one or more information technology enclosures according to an example embodiment;

FIG. 3 is a functional schematic of a rack with an exemplary smart liquid cooling manifold;

FIG. 4 depicts an exemplary communication network for transferring data from the smart manifold;

FIG. 5 is a functional schematic of an alternative embodiment of an exemplary smart manifold; and

FIG. 6 is flowchart showing an exemplary method of use of a smart manifold.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

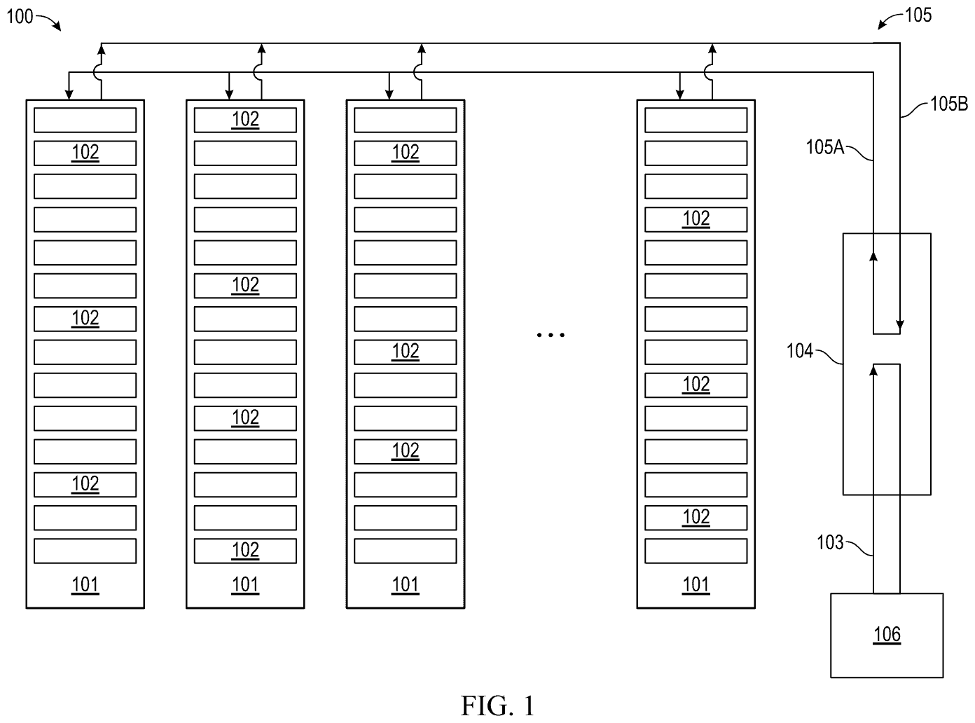

FIG. 1 illustrates a typical direct liquid cooling (“DLC”) system 100. In a server room or data center, racks 101 each hold a plurality of IHS's 102. Each IHS 102 is liquid-cooled. A coolant, such as water, flows through internal cold plates associated with the heat-generating components, such as CPUs, GPUs, and memory devices, inside each IHS 102. A primary water supply 103 from the data center facility 104 provides water to a cooling distribution unit (“CDU”) 104. The CDU 104 serves as a heat exchanger between the primary water supply 103 and a secondary cooling circuit 105 that feeds cooling fluid to racks 101 via outbound leg 105a and inbound leg 105b. The CDU 104 removes heat from the secondary cooling circuit 105.

An IHS 102 may be a single-processor system, or a multi-processor system including two or more processors. Host processors on the IHS may include any processor capable of executing program instructions, such as an INTEL/AMD x86 processor, or any general-purpose or embedded processor implementing any of a variety of Instruction Set Architectures (ISAs), such as a Complex Instruction Set Computer (CISC) ISA, a Reduced Instruction Set Computer (RISC) ISA (e.g., one or more ARM core(s), or the like). The IHS may include a chipset coupled to the host processors. The chipset may provide host processors with access to several resources on the IHS. In some cases, the chipset may utilize a QuickPath Interconnect (QPI) bus to communicate with the host processors. The chipset may also be coupled to communication interfaces to enable communications between the IHS and various wired and/or wireless networks, such as ETHERNET, WIFI, BLUETOOTH (BT), cellular or mobile networks (e.g., Code-Division Multiple Access or “CDMA,” Time-Division Multiple Access or “TDMA,” Long-Term Evolution or “LTE,” etc.), satellite networks, or the like.

The IHS 102 may assume different form factors including, but not limited to: servers, workstations, desktops, laptops, appliances, video game consoles, tablets, smartphones, etc. For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a server (e.g., blade server or rack server), a network storage device, or any other suitable device and may vary in size, shape, performance, functionality, and price.

An IHS 102 may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components.

Liquid cooling for computing racks is an attractive alternative to air cooling due in large part to the relatively dense housing of rack 101 components, which can each generate large amounts of heat. Liquid cooling is being adopted in many data centers due to significant reduction in operational expenditures compared to air cooled systems. Liquid cooling systems utilize a cold plate that replaces the CPU's heat sink. The cold plate is cooled using flexible conduits that circulate a liquid, such as a water or a blend of water and other water-based materials. With increasing demand for higher performance and density, next generation architectures will require direct liquid cooling (DLC).

In some arrangements, a single CDU 104 services a plurality of racks 101 as shown. In other arrangements, each rack 101 or small groups of racks may have their own CDU 104. Each rack 101 is associated with a rack manifold (not shown) that distributes coolant from the secondary cooling circuit 105 to each IHS 102.

CPU's and other heat-generating components within the IHS's 102 may experience over-heating due to failure of the cooling system. Usually, these failures are caused by loss of coolant flow in the secondary coolant circuit 105. Without coolant flowing through the cold plates in the IHSs 102, the temperature of the CPU's and the coolant within the cold plates increases rapidly. An IHS 102 react to elevated CPU temperatures by slowing down or completely shutting down the CPUs. Such thermal throttling results in performance reduction and any shutdown may result in data loss and/or workloads dropping offline. Despite these thermal protections, there may still be damage to the CPU cold plates due to the dramatically increased temperature of the coolant. This failure results in significant cost and downtime while these systems are repaired/replaced.

This issue arises because IHSs 102 do not know there is a problem with the secondary cooling flow 105 until it is too late. The damage has already been done or is not preventable by the time an IHS 102 is able to react. Accordingly, there is a need to prevent system damage and data loss in the event of a liquid cooling failure.

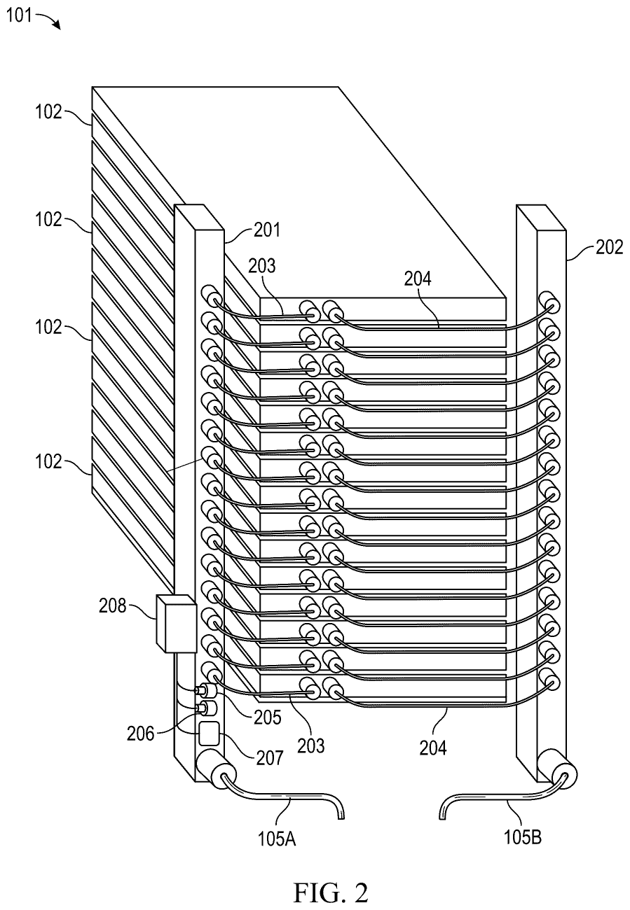

FIG. 2 illustrates the components of a liquid cooling system for an individual rack 101. Rack 101 typically has a frame structure comprising top and side panels along with rails or brackets for mounting components such as IHSs 102. Those structural elements are well known but are not shown in FIG. 2 to simplify the illustration. Rack 101 comprises a plurality of IHSs 102 stacked vertically and mounted on rails within the frame. Individual IHSs 102 are cooled using liquid cooling.

Rack 101 includes an inlet coolant manifold 201 for distributing cooled liquid 102 from the primary cooling circuit 103 to IHS's 102. An outlet coolant manifold 202 receives warmed coolant from IHSs 102 after the liquid absorbs heat from components in the IHSs 102. The inlet manifold 201 is coupled to each IHS 102 by an inlet tube 203. The outlet manifold 202, on the other hand, is fluidly coupled to each IHS 102 by an outlet tube 204. Thus, inlet manifold 201 and outlet manifold 202 enable the cooling of multiple IHS's 102 using a central cooling source (e.g., CDU 104).

Although the IHSs 102 are shown as being connected to manifolds 201, 202 by tubes 203, 204, it will be understood that the smart liquid cooling manifold disclosed herein will work with other manifold configurations. For example, the Open Compute Project 21″ standard (OCP21) will require blind mating for the IHS couplers and manifolds in the liquid cooling system. While this will increase the overall complexity of the liquid cooling system, the smart liquid cooling manifold will work with any liquid cooling system manifold configuration.

A smart liquid cooling system has sensors embedded on the supply side manifold 201. A pressure sensor 205, temperature sensor 206, and flow meter 207 are positioned on inlet manifold 201 so that the properties of the inlet coolant flow can be monitored and measured. This provides health and status information for the coolant system that can be relayed to a building management system (“BMS”), data center management console, or other monitoring system by a data acquisition (“DAQ”) device 208.

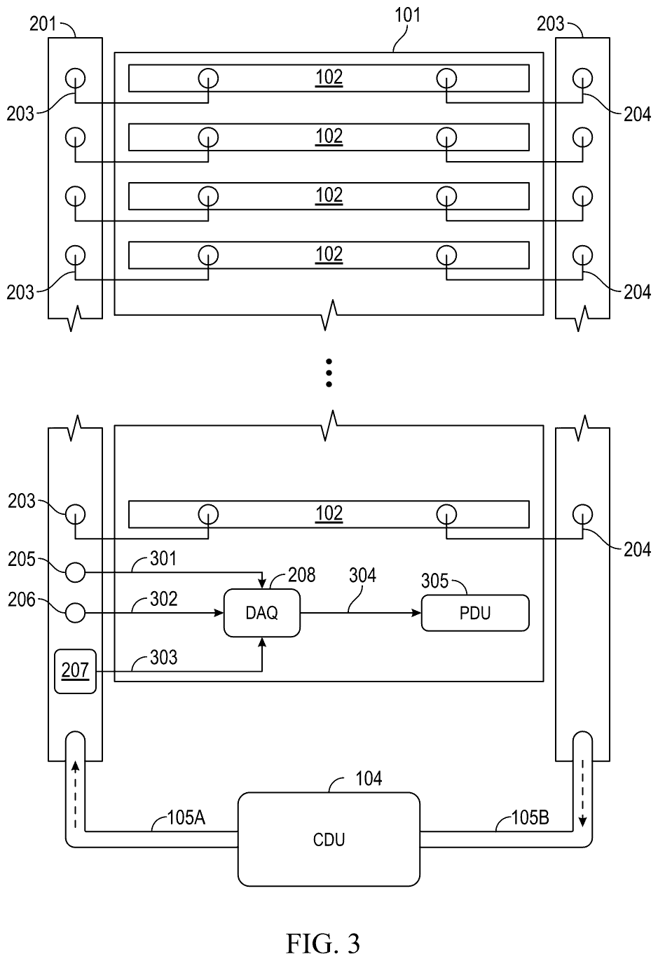

FIG. 3 is a functional schematic depicting an exemplary embodiment of a smart manifold 201 for use with rack 101 that supports a plurality of IHSs 102. Smart manifold 201 is configured to be in fluid communication with a plurality of inlet tubes 203 such that liquid coolant is distributed to each IHS 102. Heat is removed from each IHS 102 by coolant coursing through outlet tubes 204, which are in fluid communication with outlet manifold 202. Inlet manifold 201 is fed by CDU 104 though cooling circuit inlet loop 105a. Warmed coolant returns to CDU 104 from output manifold 202 via return loop 105b.

Smart manifold 201 comprises a pressure sensor 205 that generates a voltage signal 301 representing a pressure of the incoming coolant in inlet manifold 201. Smart manifold also includes a temperature sensor 206 that generates a voltage signal 302 representing pressure of the incoming coolant. Flow meter 207 is also associated with smart manifold 201 and generates a voltage signal 303 representing the flow rate of the incoming coolant. Respective voltage signals 301, 302, 303 are provided to DAQ device 208, which is configured to convert voltage signals 301, 302, 303 from analog voltages to respective digital data signals, collectively indicated at 304, which may be provided to a power distribution unit (PDU) 305 also associated with rack 101. PDU 305 is a system for distributing electric power to multiple IHSs 102 or to networking equipment within rack 101. PDU 305 helps manage power distribution efficiently and provides various features for monitoring and controlling power usage. Power required for elements of smart manifold 201 may be received from PDU 305.

Although sensors 205-207 and DAQ 208 are shown to be separate from smart manifold 201, it will be appreciated by those skilled in the relevant arts that DAQ 208 may be incorporated into inlet manifold 201. Sensors 205-207 and DAQ 208 are merely shown as a separate components for clarity and this depiction is not intended to limit any of the components from being combined in any combination or to be incorporated in whole or in part into manifold 201.

In other embodiments, the sensors 205-207 may be associated with outlet manifold 202 in addition to, or instead of, being attached to inlet manifold 201. If sensors are configured to monitor coolant parameters on both the inlet manifold 201 and the outlet manifold 202, then differential measurements may be determined for additional analysis of the coolant system (i.e., temperature, pressure, or flow rate decreases across the IHSs 102).

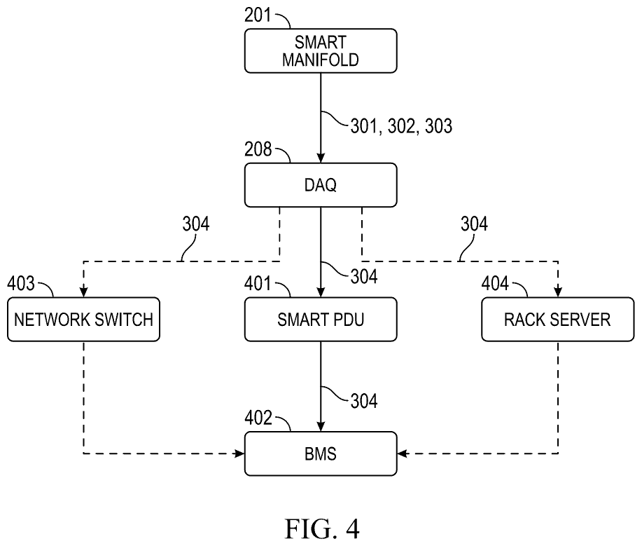

As illustrated in FIG. 4, the PDU may be a “smart” PDU 401 that is configured to receive and transmit information, such as the digital data signals 304 representing the temperature, pressure, and/or flow rate of the inlet coolant. Smart PDU 401 may also be configured to execute certain functions related to cooling management for rack 101 and IHSs 102. In one embodiment, voltage signals representing incoming coolant temperature, pressure, and/or flow rate 301, 302, 303 are received by DAQ 208 and converted to digital data signals 304. These signals 304 are then transmitted to smart PDU 401. Smart PDU 401 may then transmit the digital data signals to a BMS 402 that regulates environmental conditions of the data center facility, including the cooling systems 100. Alternatively, digital data signals 304 may be relayed from DAQ 208 to BMS 402 via a network switch 403 or a rack server 404 associated with rack 101.

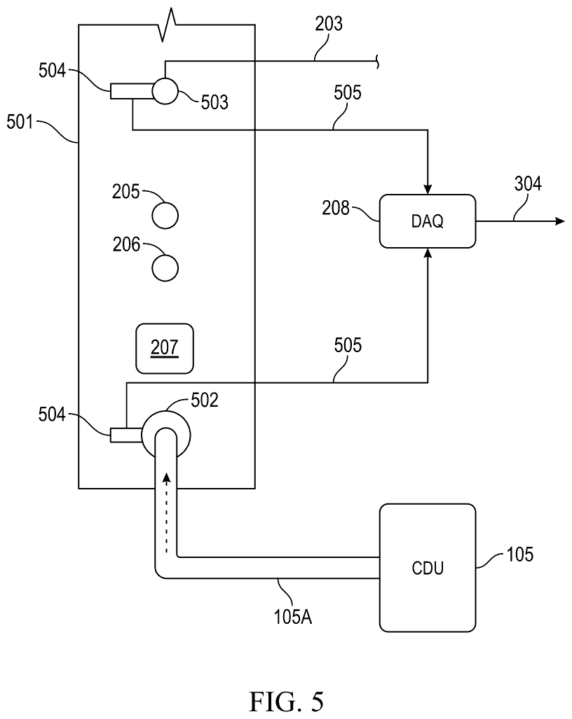

With reference to FIG. 5, an alternative embodiment of the smart manifold 501 will be described. In this example, smart manifold 501 is configured with a quick disconnect fitting 502 at the connection of coolant supply line 105a to manifold 501. A quick disconnect fitting 503 is also at the connection of inlet tubes 203 to manifold 501. A leak detector 504 is associated with each quick disconnect fitting 502, 503. If leak detector 504 encounters a leak at one of the quick disconnect fittings 502, 503, it generates a voltage signal 505 indicating the presence of a leak at the fitting and provides this signal 505 to DAQ 208 which processes and transmits a digital data signal 304 as described above.

Leak detectors 504 may be any suitable type for detecting leaks for this application. A non-limiting example of a leak detector include a capacitance sensor or a pressure-based sensor.

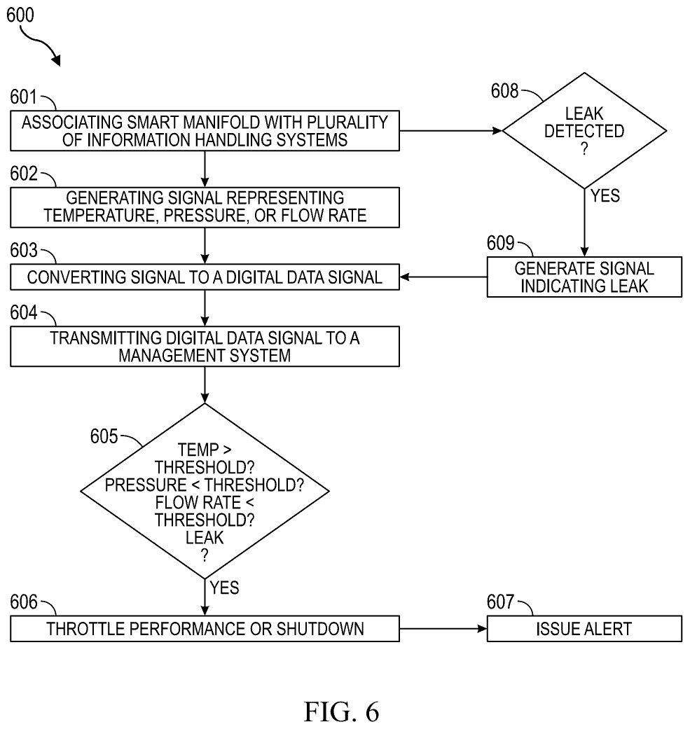

A method associated with a smart manifold 201 is shown with the flowchart 600 of FIG. 6. At 601, a smart manifold 201 is associated with a plurality of IHS's 102, where the manifold comprises a pressure sensor 205, a temperature sensor 206, and a flow meter 207. Next, a signal representing temperature, pressure, or flow rate is generated 602. At 603, that signal is converted to a digital data signal, and, at 604, the signal is then transmitted to a management system, such as a BMS.

At 605, the management system assesses whether any of the coolant parameters (temperature, pressure, or flow rate) are beyond acceptable thresholds. The management system is able to communicate directly, or through some intermediary component, to the Baseboard Management Controller (BMC) of the server IHS 102. If the parameters exceed thresholds at 605, then the management system instructs the BMC of the server IHSs 102 to throttle performance or to shut down at 606 to enact precautions to prevent data loss and damage to the IHSs 102.

At 607, the system generates an alert to indicate the existence of an issue with the cooling system. The alert may be in the form of lighting, for example, lighting on an individual IHS 102 chassis or lighting in or around racks 101. Such an alert may be a visual alert, such as an LED warning light, an audible alert, such as a tone or chime, or a textual or graphic alert rendered on a user-interface display

In embodiments where smart manifold 501 includes one or more leak detectors 504, the method concurrently performs a step 608 of monitoring the leak detector 504. If a leak is detected at 608, then a signal indicating the leak is generated at 609. The leak detection signal of at 609 may be converted to a digital data signal at 603 and the method continues as described above.

In an example embodiment, a cooling manifold for distributing liquid coolant to a plurality of liquid cooled information handling systems is responsive to a power distribution unit and housed in a data center facility the facility including a building management system. The cooling manifold comprises a temperature sensor configured to generate a temperature signal representing a temperature of the liquid coolant, a pressure sensor configured to generate a pressure signal representing a temperature of the liquid coolant, and a flow meter configured to generate a flow rate signal representing a flow rate of the liquid coolant. The cooling manifold further comprises a data acquisition device configured to convert the temperature signal, the pressure signal, and the flow meter signal into digital data. The digital data is transmitted to the building management system. The digital data is transmitted to the power distribution unit. The digital data is transmitted to the building management system.

The cooling manifold further comprises a leak detector configurated to generate a leak alert signal in the event of a leak in the cooling manifold. The cooling manifold further comprises a data acquisition device configured to convert the temperature signal, the pressure signal, the flow meter signal, and the leak alert signal into digital data. The digital data is transmitted to the building management system.

In another embodiment, an information handling system support rack comprises a plurality of liquid cooled information handling systems; a power distribution unit for managing power for the plurality of information handling systems; and a manifold for distributing liquid coolant to each of the information handling systems. The manifold comprises a temperature sensor configured to generate a temperature signal representing a temperature of the liquid coolant; a pressure sensor configured to generate a pressure signal representing a temperature of the liquid coolant; and a flow meter configured to generate a flow rate signal representing a flow rate of the liquid coolant.

The information handling system support rack further comprises a data acquisition device configured to convert the temperature signal, the pressure signal, and the flow meter signal into digital data. The digital data is transmitted to the power distribution unit and/or to the building management system.

The manifold further comprises a leak detector configured to generate a leak alert signal in the event of a leak in the cooling manifold. The data acquisition device is further configured to convert the leak alert signal into digital data. The digital data is transmitted to the building management system via one of the power distribution unit, an information handling system, and a network switch.

In another example embodiment, a method for cooling a plurality of liquid cooled information handling systems comprises the steps of associating a manifold with the plurality of information handling systems, wherein the manifold configured to distribute liquid coolant to each of the plurality of information handling systems and comprising a plurality of sensors, each of the plurality of sensors configured to generate a signal representing one of coolant temperature, coolant pressure, and coolant flow rate; and generating the signal representing one of coolant temperature, coolant pressure, and coolant flow rate.

The method further comprises converting the signal to a digital data signal; and transmitting the digital data signal to a management system. The method further comprises throttling performance of the information handling systems based upon the digital data signal. The method further comprises shutting down the information handling systems based upon the digital data signal.

The manifold is configured with at least one leak detector, and further comprising the steps of, upon encountering a leak, generating a signal indicative of the leak; converting the signal indicative of the leak to a digital signal; and transmitting the digital signal to the management system.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. A cooling manifold for distributing liquid coolant to a plurality of liquid cooled information handling systems housed in a data center facility the facility, the cooling manifold comprising:
a temperature sensor configured to generate a temperature signal representing a temperature of the liquid coolant;
a pressure sensor configured to generate a pressure signal representing a temperature of the liquid coolant; and
a flow meter configured to generate a flow rate signal representing a flow rate of the liquid coolant.

2. The cooling manifold of claim 1, further comprising a data acquisition device configured to convert the temperature signal, the pressure signal, and the flow meter signal into digital data.

3. The cooling manifold of claim 2, wherein the digital data is transmitted to a building management system.

4. The cooling manifold of claim 2, wherein the digital data is transmitted to a power distribution unit.

5. The cooling manifold of claim 4, wherein the digital data is transmitted to a building management system.

6. The cooling manifold of claim 1, further comprising a leak detector configurated to generate a leak alert signal in the event of a leak in the cooling manifold.

7. The cooling manifold of claim 6, further comprising a data acquisition device configured to convert the temperature signal, the pressure signal, the flow meter signal, and the leak alert signal into digital data.

8. The cooling manifold of claim 7, wherein the digital data is transmitted to a building management system.

9. The cooling manifold of claim 7, wherein the digital data is transmitted to a power distribution unit.

10. The cooling manifold of claim 9, wherein the digital data is transmitted to a building management system.

11. An information handling system support rack comprising:
a plurality of liquid cooled information handling systems;
a power distribution unit for managing power for the plurality of information handling systems; and
a manifold for distributing liquid coolant to each of the information handling systems, the manifold comprising:
a temperature sensor configured to generate a temperature signal representing a temperature of the liquid coolant;
a pressure sensor configured to generate a pressure signal representing a temperature of the liquid coolant; and
a flow meter configured to generate a flow rate signal representing a flow rate of the liquid coolant.

12. The information handling system support rack of claim 11, further comprising a data acquisition device configured to convert the temperature signal, the pressure signal, and the flow meter signal into digital data.

13. The information handling system support rack of claim 12, wherein the digital data is transmitted to the power distribution unit.

14. The cooling manifold of claim 13, wherein the digital data is transmitted to the building management system.

15. The cooling manifold of claim 12, wherein the manifold further comprises a leak detector configured to generate a leak alert signal in the event of a leak in the cooling manifold; and
wherein the data acquisition device is further configured to convert the leak alert signal into digital data; and
wherein the digital data is transmitted to the building management system via one of the power distribution unit, an information handling system, and a network switch.

16. A method for cooling a plurality of liquid cooled information handling systems comprising the steps of:
associating a manifold with the plurality of information handling systems, the manifold configured to distribute liquid coolant to each of the plurality of information handling systems and comprising a plurality of sensors, each of the plurality of sensors configured to generate a signal representing one of coolant temperature, coolant pressure, and coolant flow rate; and
generating the signal representing one of coolant temperature, coolant pressure, and coolant flow rate.

17. The method of claim 16, further comprising:
converting the signal to a digital data signal; and
transmitting the digital data signal to a management system.

18. The method of claim 17, further comprising:
throttling performance of the information handling systems based upon the digital data signal.

19. The method of claim 17, further comprising:
shutting down the information handling systems based upon the digital data signal.

20. The method of claim 17, wherein the manifold is configured with at least one leak detector, and further comprising the steps of:
upon encountering a leak, generating a signal indicative of the leak;
converting the signal indicative of the leak to a digital signal; and
transmitting the digital signal to the management system.
